(19) United States
(12) Patent Application Publication
(10) Pub. No.: US 2016/0360644 A1
(43) Pub. Date: Dec. 8, 2016

(54) Heat Dissipation in a Mobile Device to Enable High-Performance Desktop Functionality

(71) Applicant: Inderjit Bains, Vancouver (CA)

(72) Inventor: Inderjit Bains, Vancouver (CA)

(73) Assignee: Arctec Mobile Inc., Vancouver (CA)

(21) Appl. No.: 15/176,178

(22) Filed: Jun. 8, 2016

Related U.S. Application Data
(60) Provisional application No. 62/172,794, filed on Jun. 8, 2015.

(51) Int. Cl. H05K 7/20

(52) U.S. Cl. CPC H05K 7/20154

(57) ABSTRACT

The invention allows a mobile device such as a smart phone or tablet to be designed to dissipate heat through the battery or battery casing to the back and sides of the enclosure, which allows better passive cooling for hand-held applications, and more importantly allows the mobile device to be used as a high-performance desktop computer by plugging the mobile device into a cradle with forced-air cooling. The cradle connects to external displays, keyboards, pointing devices, storage devices, peripherals, networks, and audio devices. The invention allows a mobile device to perform desktop computing tasks on a large desktop monitor, such as browsing the Internet; writing or editing documents, emails, websites, blogs or program code; viewing, editing or converting the format of photos and videos; playing games; and playing online or downloaded videos and music, as well as allowing faster battery charging. The cradle can also be implemented in a desktop monitor, laptop frame, keyboard, large tablet, television, or projector. Finally, the invention allows all user data, system settings, operating system and applications to be kept on one device, which allows convenient backup/restore to external local storage or cloud-based storage.

### CROSS-REFERENCE OF RELATED APPLICATIONS

See Application Data Sheet.

### STATEMENT REGARDING FEDERALLY SPONSORED RESEARCH AND DEVELOPMENT

Not Applicable.

### REFERENCE TO SEQUENCE LISTING, A TABLE, OR A COMPUTER PROGRAM LISTING COMPACT DISK APPENDIX

Not Applicable.

### BACKGROUND OF THE INVENTION

Computers for personal use are currently available in desktop, laptop, tablet and mobile phone form factors. Since the late 1990's the Central Processing Unit (CPU) used in computers has evolved into a System On Chip (SOC), with integrated memory controllers, graphics, and peripherals. The SOC performance/power ratio continues to increase, and the performance gap between tablets and mobile phones is diminishing. Advanced SOCs are capable of driving multiple 1080p or higher resolution displays. The invention describes how mobile devices using these advanced SOCs can be internally designed to dissipate more heat passively, and with external forced-air cooling, provide high-performance desktop and laptop functionality. The operating system and applications will still run on the mobile device, but the user can more conveniently use a larger display screen and a standard keyboard and mouse to browse the Internet; write or edit documents, emails, websites, blogs or program code; view, edit or convert the format of photos and videos; play games; and play online or downloaded videos and music.

An SOC designed for a mobile device must balance performance with battery life. Battery life is not a factor in a desktop environment since external power is available and for a laptop, a much larger battery is available. Higher performance however requires more power consumption, mainly by the SOC, and the resulting heat must be dissipated. Mobile devices in their current state of development do now allow adequate cooling for the higher performance requirements of desktop computing. To overcome this limitation, the invention provides a means to cool the heat producing elements of a mobile device to allow it to be used as a high-performance desktop or laptop platform.

### BRIEF SUMMARY OF THE INVENTION

An object of the invention is to allow a mobile device such as a smart phone, tablet or similar device to be internally designed to dissipate heat through the battery to the back and sides of the enclosure, which will provide better passive cooling for hand-held applications, and high-performance desktop or laptop functionality with fast battery charging capability through forced-air cooling when the mobile device is plugged into a desktop cradle or a laptop frame, with an interface connector that provides signals for external displays, keyboards, pointing devices, storage devices, peripherals, networks, and audio devices.

A second object of the invention is to allow a mobile device to be used to perform standard desktop or laptop computer tasks without the need to transfer user data, such as browsing the Internet; writing or editing documents, emails, websites, blogs, or program code; viewing, editing, or converting the format of photos and videos; playing games; and playing online or downloaded videos and music.

A third object of the invention is to allow a single device to be used to store all user data, system settings, operating system and applications for convenient backup to local or cloud storage and restoration in case of theft, loss, or device malfunction.

### BRIEF DESCRIPTION OF THE DRAWINGS

FIG. 1 is a context diagram of the functionalities of the mobile device and cradle, along with the signals on the cradle connector.

FIG. 2 is an exploded view of the relevant components of a mobile phone.

FIG. 3 is an exploded view of a mobile phone with the SOC thermally coupled to the back of the enclosure through the battery.

FIG. 4 is an exploded view of a mobile phone with the SOC thermally coupled to the back of the enclosure through a battery integrated into the back of the enclosure.

FIG. 5 is an example cradle with a fan, front view.

FIG. 6 is an example cradle with a fan, back view.

FIG. 7 is a mobile device in a cradle.

FIG. 8 is a flowchart of a mobile device being plugged into and out of a cradle.

FIG. 9 is a mobile device in a cradle, showing the connections for a typical desktop setup.

### DETAILED DESCRIPTION OF THE INVENTION

The invention will be described as it applies to its preferred embodiment. It is not intended that the invention be limited as described. Rather, the invention is intended to cover all modifications and alternatives which may be included within the spirit and scope of the invention. In the following description, mobile devices include smart phones, tablets and similar devices.

As mobile devices (smart phones and tablets) become more powerful, with greater SOC performance, more RAM and non-volatile storage, their capabilities are starting to approach and exceed early desktop computers. Many mobile devices are capable of driving 1080p displays, which is the standard resolution of a desktop monitor. The invention allows a mobile device to be internally designed to dissipate heat through the back and sides of the mobile device's enclosure. With appropriate signals exposed on an interface cradle connector, the mobile device can be plugged into an appropriately designed cradle with force-air cooling, which will allow the mobile device to be used as a high-performance desktop or laptop platform. The cradle connector includes signals for external displays, keyboards, pointing devices, storage devices, peripherals, networks, and audio devices. In some implementations, wireless connections from the mobile device to external displays, keyboards, pointing devices, storage devices, peripherals, networks, and audio devices may be implemented instead of electrical signals on the interface connector, depending on the capabilities of the SOC and supporting circuitry in the mobile device.

To keep the mobile device design as small and low power as possible, the physical interface or controller ICs for some functions, such as Ethernet PHY, USB Hub, and video I/O interface, unless they are included in the SOC, can be located in the cradle. The cradle connector also includes power to recharge the mobile device's battery while it is being used in desktop mode. The list of signals on the cradle connector can include but is not limited to the following:
1. HDMI/DVI/DisplayPort/VGA
2. 10/100/1000 Ethernet MII/RGMII
3. USB Host/OTG, with a USB Hub in the cradle
4. XD/SD/MMC Card, and similar card slot signals
5. SATA/Mini PCI Express
6. Audio, for a wired headset (front) and speakers and microphone (back)
7. Cradle detection circuitry
8. Fan speed control
9. Power (e.g. +5V) to power the mobile device and to charge the mobile device's battery

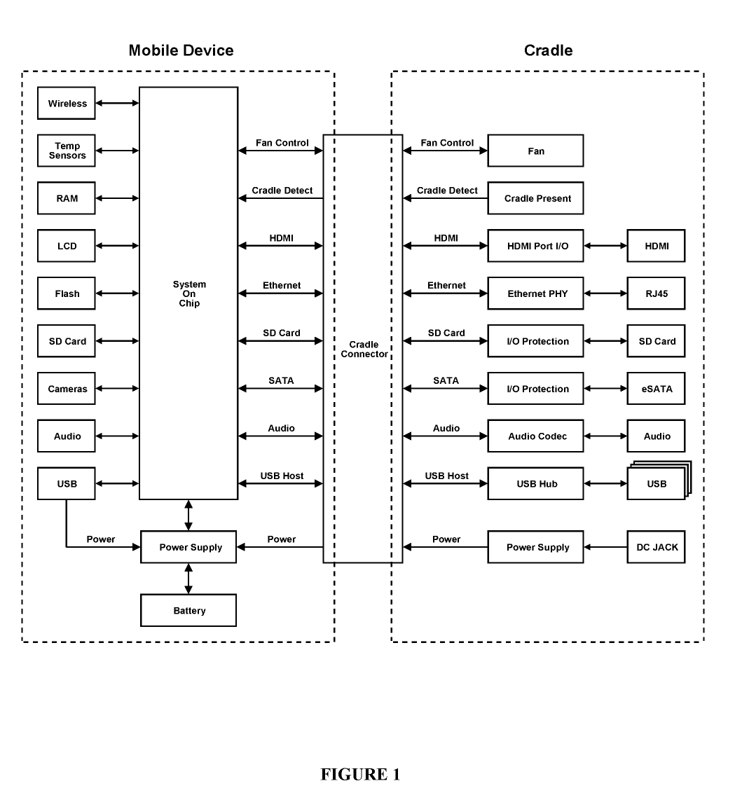

An example context diagram of the functionalities of a mobile device and a cradle, along with the signals on the cradle connector is shown in FIG. 1. To allow greater heat dissipation when the mobile device is used as a desktop computer, a cooling fan is built-in to the cradle, with its speed controlled by the mobile device with inputs from internal temperature sensors, located in or near the SOC, PCB, battery, high-power components, etc.

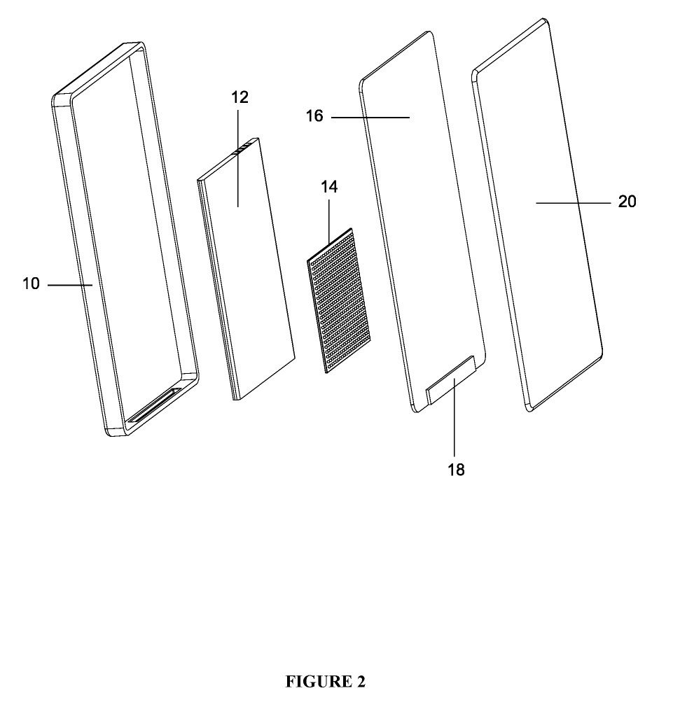

The mobile device is designed to thermally couple the SOC and other high power components to the back and sides of the mobile device's enclosure, which is made of metal or thermally conductive material. A simplified exploded view of a mobile device is shown in FIG. 2, which includes, from left to right, the back of the enclosure (10), battery (12), SOC (14), PCB (16), cradle connector (18), and LCD (20). While the battery can be placed between the LCD and the PCB, there are several advantages in dissipating the heat from the SOC and other high power components through the battery and battery casing. First, the overall design of the mobile device can be made as compact as possible with the battery in physical contact with the back of the enclosure. Second, while charging of Li-Ion and LiFEPO₄ batteries is endothermic at low charge rates (˜<0.2 C), charging becomes exothermic at higher charge rates (˜>1 C). For a fast battery charging while in the cradle, heat from battery can be dissipated by external forced-air cooling, along with heat from the SOC. Third, when the mobile device is not on the cradle, the battery will have much larger heat sink for momentary high current draws, heat which can then be passively dissipated through radiation and natural convection.

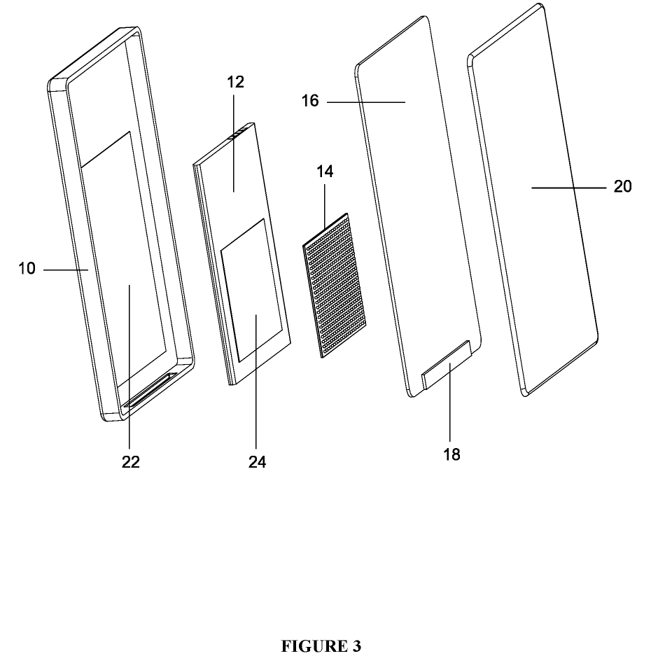

One way to dissipate heat through the battery is to make the battery casing from a thermally conductive material, and as shown in FIG. 3, use thermally conductive pads or thermally conductive filling material between the SOC and battery (24), and between the battery and the back of the enclosure (22). Example: an 80×60×5 mm battery, a wall thickness of 1 mm for the casing, and a thermal conductivity of 205 W/m° C. (aluminum), 20 W can be passed through the walls of the battery with a temperature difference of 1.7° C. from SOC to ambient (formula Q/t=kA(Tₕₒₜ−T_{cold})/d, where Q/t=heat loss rate, k=thermal conductivity, A=wall cross-sectional area, d=wall depth).

Materials with higher thermal conductivity, such as copper, can be used to reduce the wall thickness or conduct more heat with a lower temperature drop. For a battery with more than one cell, the internal walls of the battery that separate the cells can be made thermally conductive to further enhance the battery's overall heat transfer capability.

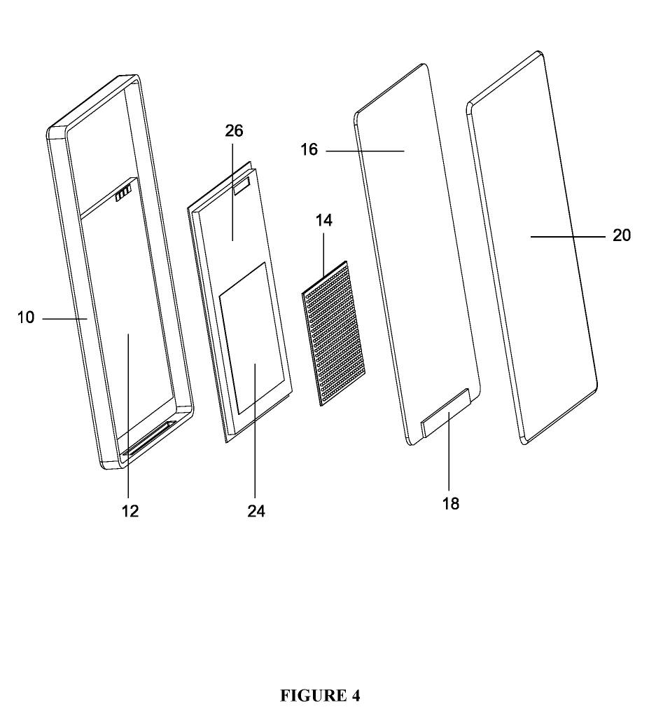

Newer battery technologies, such as lithium iron phosphate (LiFePO₄), while providing lower energy density than standard Li-Ion technology, can be charged with an ambient temperature up to 60° C. or higher, eliminating the need to insulate the battery in the battery casing. Thermally bonding the battery to the battery casing will allow heat from exothermic reactions in the battery to be dissipated. Battery technologies that provide relatively high thermal conductivity compared to standard batteries allow heat to be dissipated directly through the battery, with a heat spreader on the SOC side to evenly distribute the heat through the battery. Some LiFePO₄ batteries, for example, provide a thermal conductivity of >0.5 W/m° C. For an 80×60×5 mm battery, a temperature difference of 15° C. from SOC to ambient, and a thermal conductivity of 0.5 W/m° C., up to 7 watts of heat can pass through the battery. Additionally, as shown in FIG. 4, the battery (12) can also be completely integrated into the back of the thermally conductive enclosure (10), with the heat spreader (26) wrapping around the battery and thermally connecting to the back of the enclosure; the back of the enclosure and heat spreader thus effectively becoming the battery's thermally conductive casing, saving space in the mobile device.

Thermal coupling of the SOC and battery to the back and sides of the enclosure of the mobile device will provide additional heat dissipation through radiation and natural convection. With external forced-air cooling, more heat can be dissipated. Example: an 80×60×5 mm battery with a thermally conductive 1 mm thick walls, an 80×70×1 mm finless heat sink (the back of the mobile device), with an airflow of 30 Cubic Feet Per Minute (CFM), can dissipate 20 W of heat from a 20×20 mm heat source, with the battery casing's interface of thickness of 5 mm (thermal conductivity 205 W/m° C.), with a temperature rise of ˜20° C. for the heat source. Dissipation of 10 W under the same conditions will result in a temperature rise of ˜10° C. Passing heat through the battery alone, without a thermally conductive battery casing, will lower the amount of heat that can be dissipated, because of the lower effective thermal conductivity, but will allow a more compact mobile device to be designed.

The battery and/or battery casing, thermally conductive pads or filling material, SOC and high power component packages, and PCB mounts should be designed to absorb mechanical stress from the enclosure, if the enclosure itself cannot be designed to provide sufficient shock absorption to alleviate stress on the battery, SOC and high power components if the mobile device is dropped or mechanically stressed.

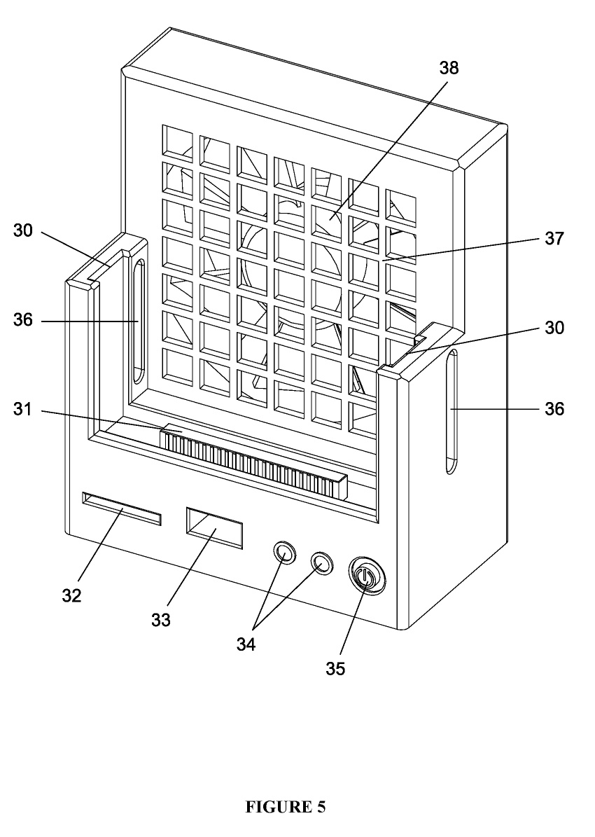

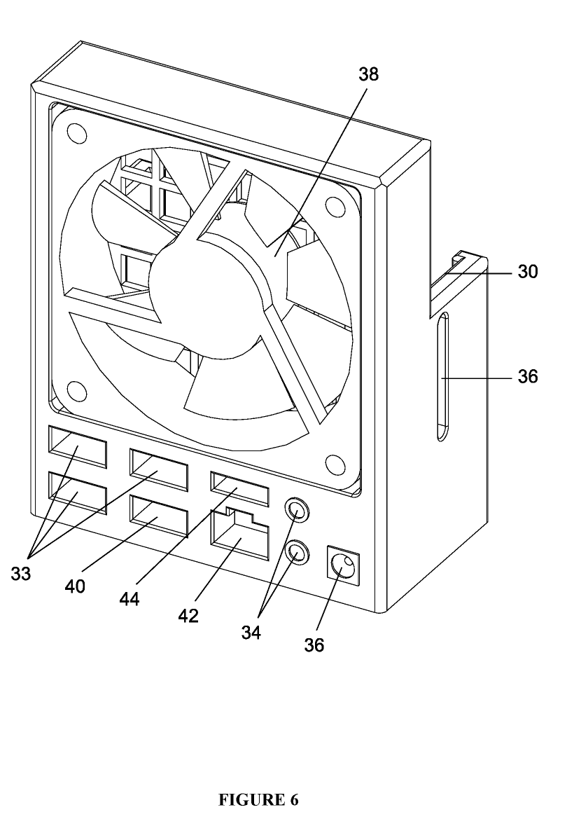

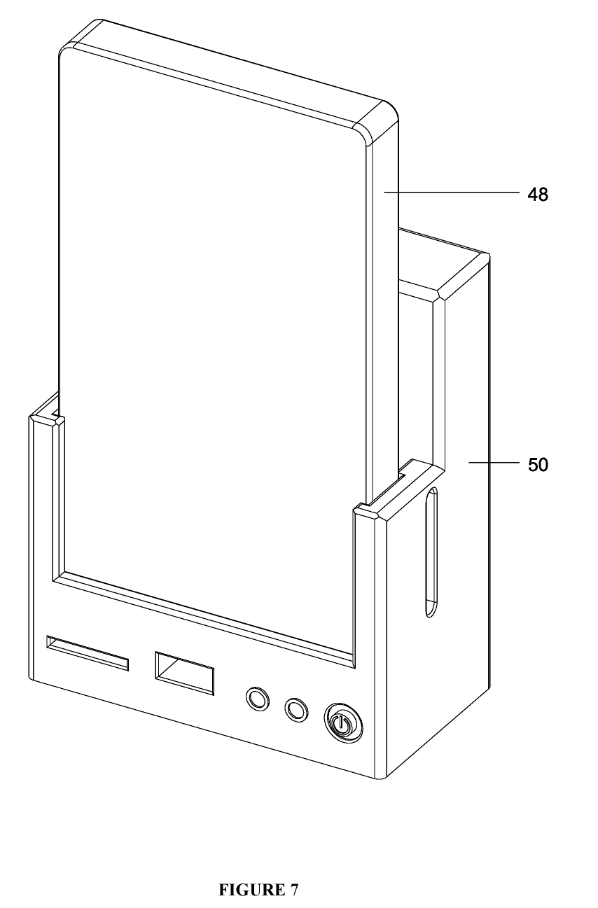

The invention may be implemented as a mobile device such as a smart phone or tablet plugged into a vertical, free-standing cradle. An example cradle, with guide rails for the mobile device (30), cradle connector (31), SD Card connector (32), USB ports (33), audio jacks (34), power button (35), eSATA port (40), Ethernet connector (42), HDMI connector (44), DC jack (36), air vents (36), fan grille (37), and fan (38) is shown in front view in FIG. 5 and back view in FIG. 6. A mobile device (48) is shown plugged into a cradle with a fan (50) in FIG. 7. The cradle may also be incorporated into another device, such as a desktop monitor, laptop frame, keyboard, large tablet, television, or projector. In each case, the operating system and applications will continue to run on the mobile device, but the user will be able to use the convenience of the larger display, along with peripherals and higher performance from forced-air cooling.

The signals on the cradle connector are hot-pluggable—the cradle and mobile device can be powered on when the mobile device is plugged into the cradle. The mobile device will detect when it gets plugged into the cradle (through a signal on the cradle connector, availability of power, detection of interface ICs or peripherals on the cradle); power on and configure the cradle's on-board controllers for USB, Ethernet, audio ports, etc.; power on external peripherals such as keyboards, pointing devices, storage devices, peripherals, networks, and audio devices.

“High Performance Desktop Mode,” will be enabled, which will drive the external monitor instead of the mobile device's display or will operate in dual-screen mode. The user interface for a large display with available user inputs (keyboard, mouse, touch screen) will be configured, and SOC's maximum clock frequencies will be increased (core, graphics, memory, and I/O where applicable) to provide higher performance, and the user will be authenticated. The battery's charge rate will also be increased if the battery and internal charger have been designed to allow a higher charge rate when additional heat dissipation is available in the cradle. External monitors with a touch screen can be supported through auxiliary data on DisplayPort or through USB.

The mobile device can connect to the Internet through the cradle's Ethernet connection, or through its built-in WiFi, Bluetooth, or mobile telecommunications connections while plugged into the cradle, depending on availability and user preference. While in “High Performance Desktop Mode,” the mobile device will monitor the temperatures of the SOC, PCB, battery, and high-power components and adjust the cradle's fan speed accordingly. If adequate cooling cannot be provided, the SOC core, graphics, memory, and I/O clock speeds, and battery charge rate will be scaled back. In most implementations, the external temperature of the mobile device should not be allowed to exceed 45° C., to prevent burns if the device can be touched. Also while in “High Performance Desktop Mode,” the user can make or receive phone calls through a wired or wireless headset or use the speakerphone feature, if available, while the mobile device is plugged into the cradle.

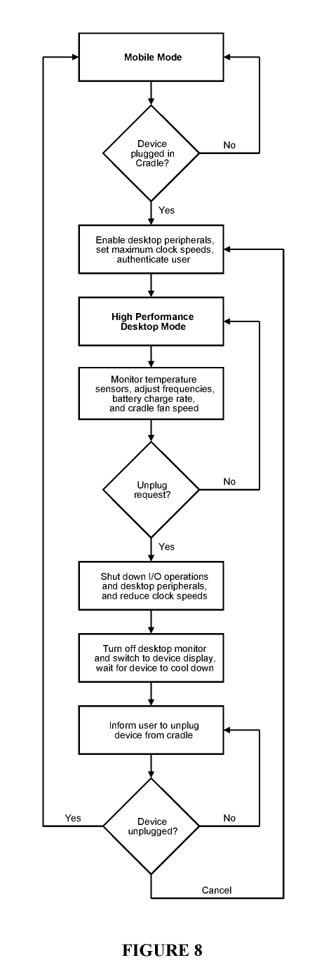

When unplugging the mobile device from the cradle, the user must first select “Unplug” from a list of operating modes to ensure that any open files on external storage devices are closed. The external monitor will then be turned off, the SOC clock frequencies reduced to “Mobile Mode”, and when the mobile device has cooled down enough to be comfortably handled, the user will be informed that the mobile device can be unplugged from the cradle. A cancel option at this point will re-enter “High Performance Desktop Mode” after user authentication without the need to unplug/replug the mobile device. Once the user unplugs the mobile device, it will operate in “Mobile Mode” until it's plugged into the cradle again. A flowchart of a mobile device being plugged into and out of a cradle is shown in FIG. 8.

The advantages of using a mobile device in a secondary role of a desktop or laptop computer are many: the user can conveniently keep all contacts, documents, photos, videos, etc. on one device, lowering cost. All user data, system settings, operating system and applications can be backed up from one device to an external data storage device or to cloud-based storage. If the mobile device is lost, stolen or stops working, the user data, system settings, operating system and applications can be restored to another mobile device. Finally, “High Performance Desktop Mode,” will provide a better user experience with faster response to the user's inputs and the ability to run applications that are impossible to run in “Mobile Mode,” because of performance limitations or screen size.

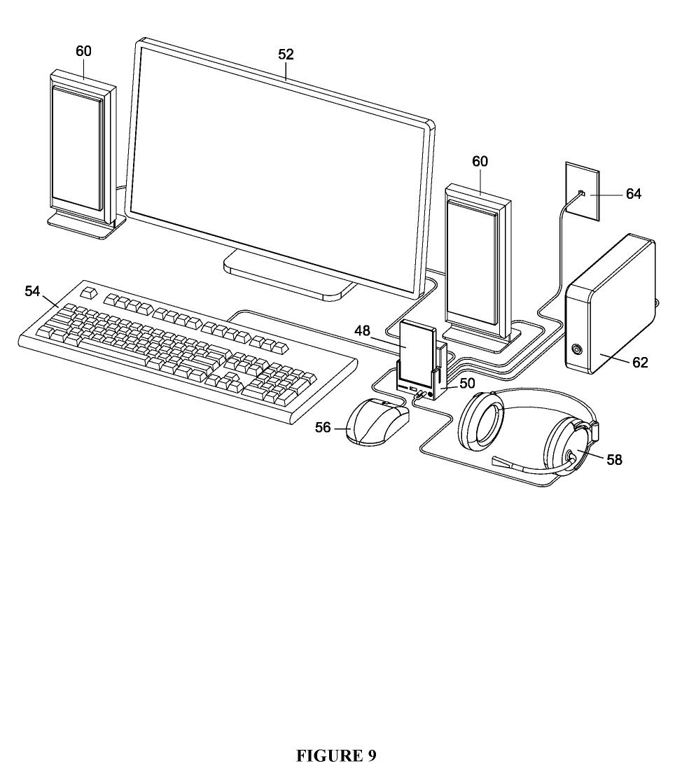

A typical desktop setup, with an LCD monitor (52), keyboard (54), mouse (56), headset (58), speakers (60), external storage device (62), and Ethernet connection (64) all connected to a mobile device (48) in a cradle with a fan (50) is shown in FIG. 9. Note that the mobile device can also connect to peripherals such as external displays, keyboards, pointing devices, storage devices, peripherals, networks, and audio devices, etc., through appropriate wireless communications standards.

1. A method or apparatus for dissipating heat in a mobile device such as smart phone, tablet, or similar device, by thermally coupling the high power components, such as but not limited to the CPU/System On Chip (SOC) and memory chips, through the battery or battery casing, the casing made of a material with high thermal conductivity, to the back and/or sides of the enclosure of the mobile device, which is made of a material with high thermal conductivity, to provide better passive cooling for hand-held applications, and when plugged into a cradle with force-air cooling over the back and/or sides of the mobile device for greater heat dissipation, allows the mobile device to be used in a high-performance desktop configuration with higher clock speeds, with the operating system and applications running on the mobile device.

2. A method or apparatus of claim 1, wherein said high power components are thermally coupled to the back of the enclosure through a battery casing made of a material with a high thermal conductivity, with or without internal walls made of a material with high thermal conductivity separating one or more cells, and with thermally conductive pads or filling material between the high power components and battery as well as the battery and back of the enclosure.

3. A method or apparatus of claim 1, wherein said high power components are thermally coupled to the back of the enclosure directly through a battery which has a relatively high thermal conductivity with a heat spreader made of high thermal conductivity on the high power component side, with thermally conductive pads or filling material between the high power components and the heat spreader as well as the battery and back of the enclosure.

4. A method or apparatus of claims 1, and 3, wherein said battery and heat spreader are integrated into the back of the enclosure; the heat spreader and back of the enclosure effectively forming the battery casing.

5. A method or apparatus of claims 1, 2, 3 and 4, wherein said battery is charged or discharged at a higher rate than normal, with the excess heat from the battery's exothermic reactions dissipated through the back of the mobile device's enclosure, through radiation, natural convection, or forced-air cooling.

6. A method or apparatus of claim 5, wherein said enclosure, battery, battery casing, thermally conductive pads or filling material, SOC and high power component packages, as well as other internal components such as but not limited to PCB mounts, alone in or in combination, are designed to alleviate mechanical stress on the SOC and high power components if the mobile device is dropped or mechanically stressed.

7. A method or apparatus of claim 6, wherein said mobile device is plugged into a cradle through an interface connector that supports some or all of, but is not limited to, hot-pluggable signals for HDMI/DVI/DisplayPort/VGA, Ethernet, USB, SATA, SD Card, Audio, and power, allowing the mobile device to connect to external displays, keyboards, pointing devices, storage devices, peripherals, networks, and audio devices, etc. through connectors on the cradle.

8. A method or apparatus of claim 7, wherein said mobile device communicates with some or all external displays, keyboards, pointing devices, storage devices, peripherals, networks and audio devices, etc. wirelessly.

9. A method or apparatus of claim 8, wherein said mobile device is designed to control the speed of the fan in the cradle with inputs from temperature sensors in the mobile device, such as but not limited to temperature sensors in the SOC, PCB, battery and high-power components, increasing the fan speed as the temperature of the mobile device increases and decreasing the fan speed as the temperature decreases, thereby keeping the fan as quiet as possible. In situations where temperature sensors indicate that adequate cooling cannot be provided, the SOC performance and battery charge rate are scaled down.

10. A method or apparatus of claim 9, wherein said mobile device and cradle are used to perform tasks commonly associated with a desktop computer without the need to transfer user data, which include but are not limited to browsing the internet; writing or editing documents, emails, websites, blogs or program code; viewing, editing or converting the format of photos and videos; playing games; and playing online or downloaded videos and music.

11. A method or apparatus of claim 10, wherein said mobile device and cradle are used to backup user data, system settings, operating system and applications to an external storage device or cloud storage so that the user data, system settings, operating system and applications can be restored to another mobile device should the original mobile device be lost, stolen, or stop functioning.

12. A method or apparatus of claim 11, wherein said mobile device automatically detects when it is plugged into a cradle, through a signal on the interface connector, availability of external power, the detection of peripheral ICs on the cradle's circuit board, the detection of special ID chips on the cradle's circuit board, or external peripherals plugged into the cradle.

13. A method or apparatus of claim 12, wherein said mobile device, upon detecting that it has been plugged into a cradle, automatically configures itself for Desktop Mode by enabling the external display interface, detecting and configuring the external monitor, detecting and configuring USB hub chips in the cradle or USB hubs plugged into the cradle, detecting and configuring peripherals plugged into the USB ports, enabling audio ports for the cradle, detecting and enabling Ethernet and connecting to the Internet, enabling any other peripherals on the cradle, setting higher maximum SOC and I/O clock speeds, faster battery charging, and authenticating the user.

14. A method or apparatus of claim 13, wherein said mobile device upon detecting and configuring the cradle's functions, operates in dual-screen mode, keeping the mobile device's own display active for user interaction in addition to activating the desktop monitor, or in single-screen mode where the mobile device's own display is inactive during Desktop Mode, thereby reducing the performance requirements of the mobile device's SOC.

15. A method or apparatus of claim 14, wherein said cradle is incorporated into another device, such as but not limited to a desktop monitor, laptop frame, keyboard, large tablet, television, or projector.

16. A method or apparatus of claim 15, wherein said mobile device connects to the Internet through Ethernet, WiFi, Bluetooth, or mobile telecommunications while plugged into the cradle.

17. A method or apparatus of claim 16, wherein said mobile device communicates with external displays, keyboards, pointing devices, storage devices, peripherals, networks, and audio devices wirelessly.

18. A method or apparatus of claim 17, wherein said cradle automatically powers on ICs and external peripherals in the cradle, such as but not limited to USB hubs, Ethernet transceivers, USB devices, SD Cards, and audio amplifiers when the mobile device is plugged into the cradle, or allows the user to manually turn cradle power on or off.

19. A method or apparatus of claim 18, wherein said mobile device allows a user to make or receive phone calls through a wired or wireless headset or through speakerphone while the mobile device is plugged into the cradle.

20. A method or apparatus of claim 19, wherein said cradle provides enough power to the mobile device to run in Desktop Mode with higher maximum SOC and I/O clocks while simultaneously charging the mobile device's battery.
